(19) United States
(12) Patent Application Publication
(10) Pub. No.: US 2005/0230738 A1
(43) Pub. Date: Oct. 20, 2005

(54) NAND type flash memory device, and method for manufacturing the same

(75) Inventor: Byoung Ki Lee, Kyungki-Do (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Kyungki-Do (KR)

(21) Appl. No.: 10/887,400

(22) Filed: Jul. 8, 2004

(30) Foreign Application Priority Data
Apr. 19, 2004 (KR) 2004-26769

(51) Int. Cl. H01L 21/8236

(52) U.S. Cl. 257/315

(57) ABSTRACT

The present invention discloses a NAND type flash memory device and a method for manufacturing the same which can prevent patterns from being collapsed or thinly defined due to irregularity, by forming word lines or source and drain select lines in regular patterns, by electrically connecting floating gates and control gates of the select lines, by forming a dielectric layer and a polysilicon layer for protection on the whole surface of a semiconductor substrate on which a polysilicon layer for floating gates has been formed, partially removing the dielectric layer on the polysilicon layer which will be the source and drain select lines, and forming a polysilicon layer for control gates and a silicide layer.

### BACKGROUND

1. Field of the Invention

The present invention relates to a NAND type flash memory device, and a method for manufacturing the same, and more particularly to, a NAND type flash memory device which can improve patterning properties of word lines or select lines and integration, and a method for manufacturing the same.

2. Discussion of Related Art

A semiconductor memory device includes a cell for storing data, and peripheral transistors for supplying an external voltage to the cell to operate the cell.

A NAND type flash memory device is one of the semiconductor memory devices. A few memory cell transistors of the NAND type flash memory device are coupled through a string structure. A select transistor is required to select the string.

FIG. 1 is a layout diagram illustrating a cell array of a conventional NAND type flash memory device.

Referring to FIG. 1, a plurality of active regions are formed in parallel to each other in a predetermined region of a semiconductor substrate. An impurity is implanted into the active regions 101. In addition, drain select lines DSL, word lines WLa1 to WLan and WLb1 to WLbn, and source select lines SSL are formed on the semiconductor substrate in the vertical direction to the active regions 101. Gate lines are also formed.

The NAND type flash memory device includes two kinds of select transistors. First, a drain select transistor for supplying a current to a cell transistor is operated as a drain in a general MOSFET. Gates of the drain select transistors are electrically connected to each other, to form gate lines. The gate lines become the drain select lines DSL. Second, a source select transistor is operated as a source in the general MOSFET. Gates of the source select transistors are electrically connected to each other, to form gate lines. The gate lines become the source select lines SSL.

That is, the NAND type flash memory device includes the active regions 101, the drain select lines DSL and the source select lines SSL. The drain select transistors are formed in the intersections between the active regions 101 and the drain select lines DSL, and the source select transistors are formed in the intersections between the active regions 101 and the source select lines SSL. Flash memory cells are formed in the intersections between the active regions 101 and the word lines WLa1 to WLan and WLb1 to WLbn.

Here, the word lines WLa1 to WLan and WLb1 to WLbn are formed in a stack gate shape, but the source select lines SSL or the drain select lines DSL are not formed in a stack gate shape. Therefore, floating gates and control gates of the source select lines SSL or the drain select lines DSL must be electrically connected to each other. The floating gates and the control gates are coupled by forming the source select lines SSL and the drain select lines DSL, forming contacts 102 in predetermined areas of the select lines, and filling a conductive material in the contacts 102. Here, wide gate pads 102a must be formed around the contacts 102 to obtain a contact area. In this case, photoresist patterns for defining the select lines DSL or SSL or the word lines WLa1 to WLan and WLb1 to WLbn are collapsed as shown in FIG. 2A (103), or the select lines DSL or SSL are thinly defined as shown in FIG. 2B (104) because of irregularity of patterns of the select lines DSL or SSL, thereby increasing resistances.

Moreover, integration is not improved due to the gate pads 102a, and is restricted in a patterning process of select gates.

### SUMMARY OF THE INVENTION

The present invention is directed to a NAND type flash memory device and a method for manufacturing the same which can prevent patterns from being collapsed or thinly defined due to irregularity, by forming word lines or source and drain select lines in regular patterns, by electrically connecting floating gates and control gates of the select lines, by forming a dielectric layer and a polysilicon layer for protection on the whole surface of a semiconductor substrate on which a polysilicon layer for floating gates has been formed, partially removing the dielectric layer on the polysilicon layer which will be the source and drain select lines, and forming a polysilicon layer for control gates and a silicide layer.

One aspect of the present invention is to provide A NAND type flash memory device, including: tunnel oxide patterns formed on a semiconductor substrate; first polysilicon patterns formed on the tunnel oxide patterns, wherein the first polysilicon patterns include a first group for floating gates and a second group for parts of select lines; dielectric patterns formed on the floating gates; and conductive patterns including first conductive patterns formed on the dielectric patterns and second conductive patterns formed on the second group of the first polysilicon patterns, wherein the first conductive patterns form control gates and second conductive patterns form select lines with the second group of the first polysilicon patterns.

According to another aspect of the present invention, a method for manufacturing a NAND type flash memory device includes the steps of: providing a semiconductor substrate on which an element isolation layer is formed in an element isolation region and a stacked structure of a tunnel oxide layer and a first polysilicon layer is formed on an active region between the element isolation layers at regular intervals; forming a dielectric layer over the resulting structure including the first polysilicon layer; removing the dielectric layer in presumed source select line or drain select line formation regions; sequentially forming a second polysilicon layer, a silicide layer and hard mask patterns over the resulting structure including the dielectric layer; and forming a plurality of word lines and a plurality of select lines, by sequentially performing an etching process and a self aligned etching process using the hard mask patterns as an etch barrier layer.

Here, the dielectric layer is protectively removed after a polysilicon layer for protection is formed on the dielectric layer.

The dielectric layer is partially removed so that the dielectric layer can be left in part of the presumed source select line or drain select line formation regions.

The etching process is performed by using the dielectric layer as the etch barrier layer in the region in which the dielectric layer is left, and using the tunnel oxide layer as the etch barrier layer in the region in which the dielectric layer is removed.

A photoresist pattern is formed in the region in which the tunnel oxide layer is exposed according to the etching process prior to the self aligned etching process.

### BRIEF DESCRIPTION OF THE DRAWINGS

FIG. 1 is a layout diagram illustrating a cell array of a conventional NAND type flash memory device;

FIGS. 2A and 2B are sectional photographs showing problems caused by irregularity of select lines;

FIG. 3 is a layout diagram illustrating a NAND type flash memory device in accordance with a preferred embodiment of the present invention; and

FIGS. 4A to 4F are cross-sectional diagrams illustrating sequential steps of a process, taken along line A-A′ of FIG. 3.

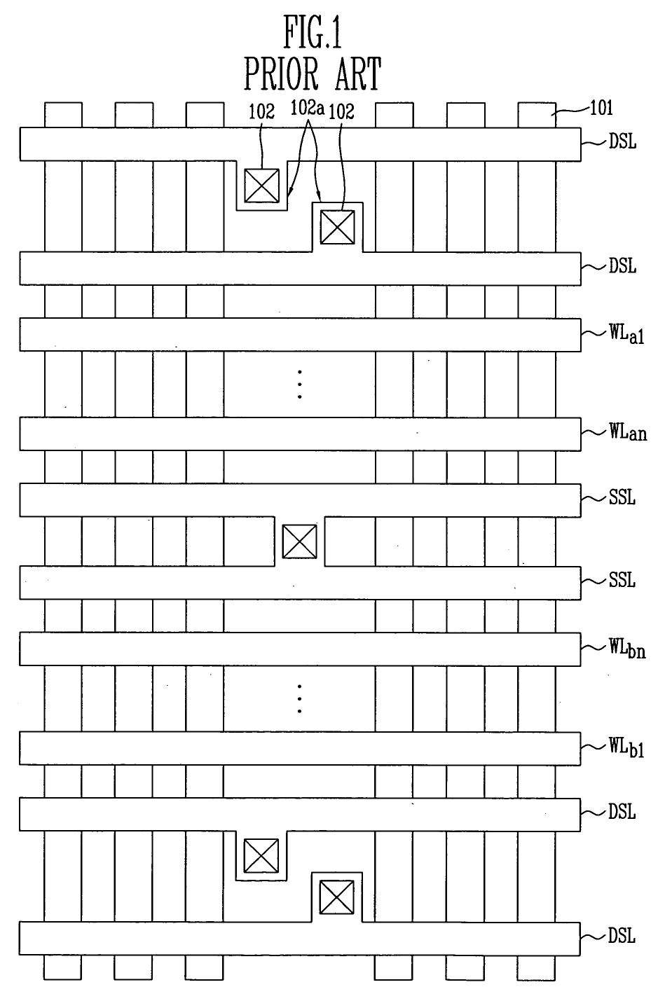

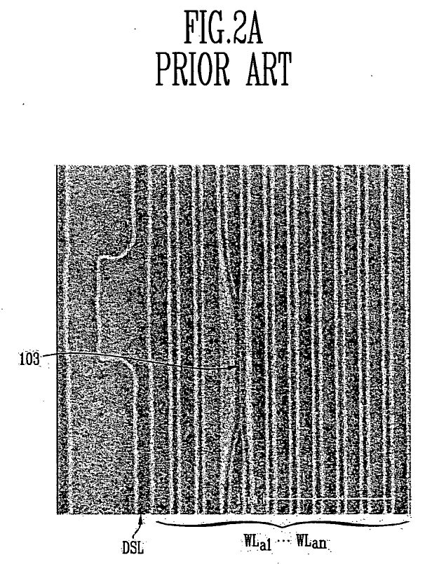

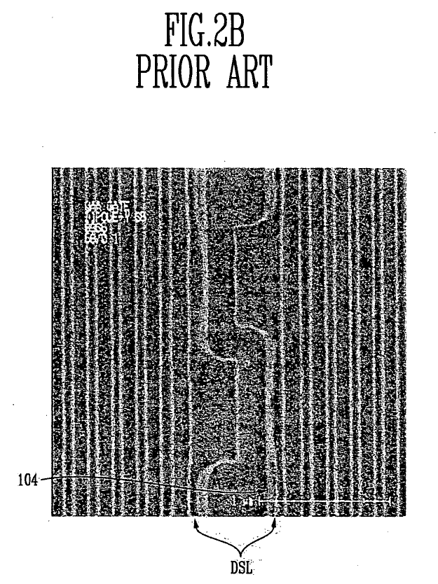

### DETAILED DESCRIPTION OF PREFERRED EMBODIMENTS

A NAND type flash memory device, and a method for manufacturing the same in accordance with a preferred embodiment of the present invention will now be described in detail with reference to the accompanying drawings. Wherever possible, the same reference numerals will be used throughout the drawings and the description to refer to the same or like parts.

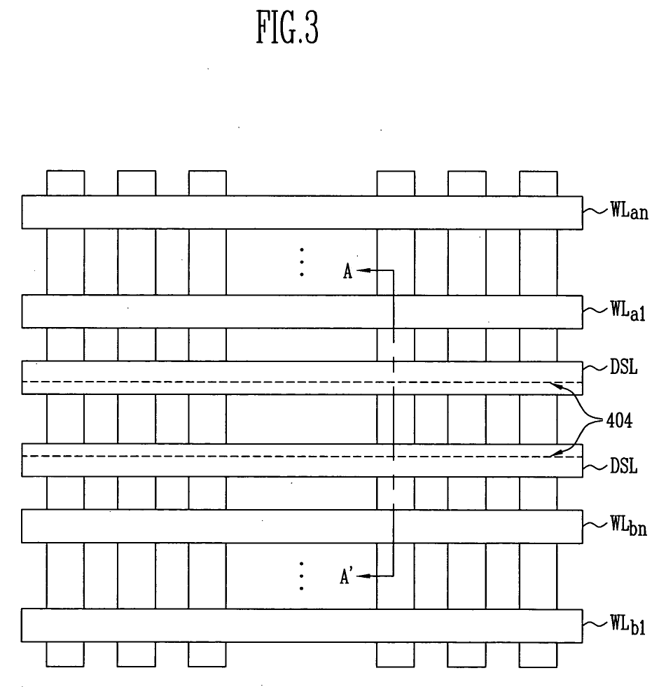

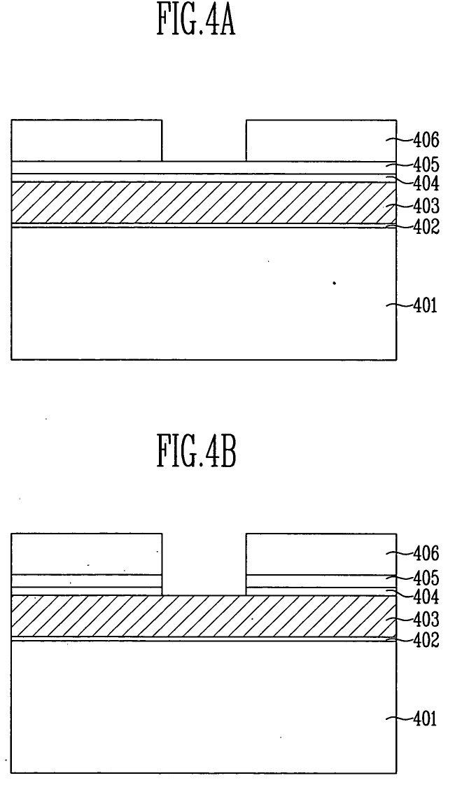

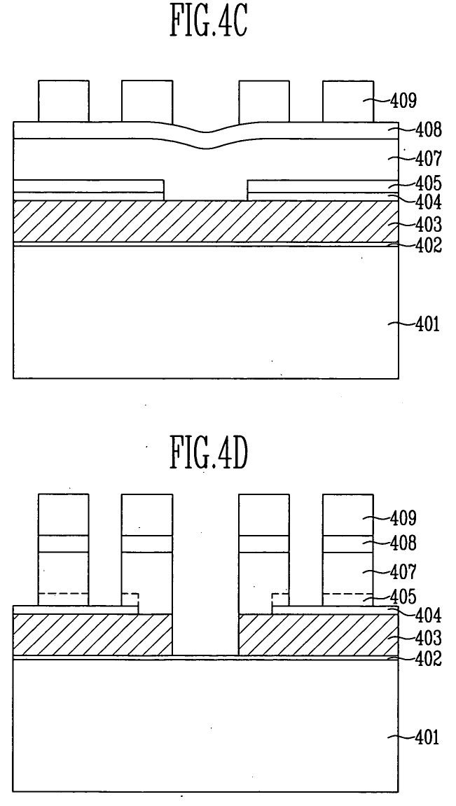

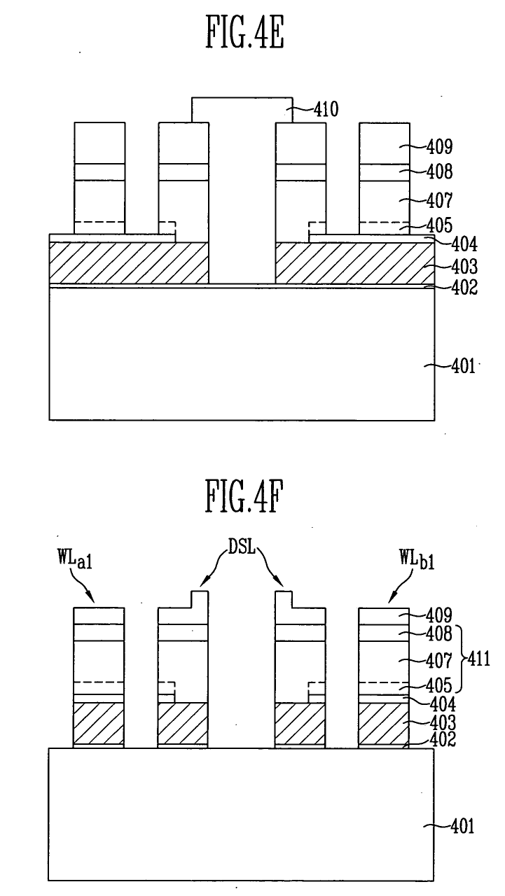

FIG. 3 is a layout diagram illustrating the NAND type flash memory device in accordance with the preferred embodiment of the present invention, and FIGS. 4A to 4F are cross-sectional diagrams illustrating sequential steps of the process, taken along line A-A′ of FIG. 3.

As illustrated in FIGS. 3 and 4A, there is provided a semiconductor substrate 401 on which an element isolation layer (not shown) is formed in an element isolation region and a stacked structure of a tunnel oxide layer 402 and a first polysilicon layer 403 for floating gates is formed in an active region including a cell region. Here, the first polysilicon layer 403 and the tunnel oxide layer 402 are patterned in the cell region in the same direction as the element isolation region, and left on the active region between the element isolation regions. On the other hand, when the first polysilicon layer 403 is formed according to a self aligned shallow trench isolation (SA-STI) method, the edges of the first polysilicon layer 403 overlap with the element isolation layer (not shown).

A dielectric layer 404 is formed over the resulting structure including the first polysilicon layer 403, and a second polysilicon layer 405 for protecting the dielectric layer 404 is formed on the dielectric layer 404. Preferably, the second polysilicon layer 405 is formed at a thickness corresponding to a half of an interval between the first polysilicon layers 403, so that the second polysilicon layer 405 can be stably deposited between the first polysilicon layers 403. The second polysilicon layer 405 can be formed at a thickness of 300 to 500 Å according to a design rule. Here, the dielectric layer 404 can be formed as an ONO structure dielectric layer.

Photoresist patterns 406 are formed on the second polysilicon layer 405. The photoresist patterns 406 are formed to define regions between drain select lines or source select lines which will be formed in a succeeding process. Here, the photoresist patterns 406 define the regions between the drain select lines or the source select lines larger than a target width. For example, the photoresist patterns 406 open the drain select line regions or the source select line regions, so that the dielectric layer 404 can not be left on the drain select lines or the source select lines, or partially open the regions between the drain select lines or the source select lines, so that the dielectric layer 404 can be left by 10 to 50 nm.

As shown in FIGS. 3 and 4B, the second polysilicon layer 405 and the dielectric layer 404 are sequentially etched by using the photoresist patterns 406 as an etch mask. Preferably, the second polysilicon layer 405 or the dielectric layer 404 is etched according to a dry etching method using plasma. On the other hand, the dielectric layer 404 can be etched according to a wet etching process using chemicals. Accordingly, the dielectric layer 404 is removed between the presumed source select line or drain select line formation regions, and partially removed on the select lines.

In this embodiment, the dielectric layer 404 is partially removed to be left in part of the presumed source select line or drain select line formation regions. However, it is also possible to remove the whole dielectric layer 404 in the presumed source select line or drain select line formation regions.

When the second polysilicon layer 405 and the dielectric layer 404 are removed in the cell region, they are also removed in a peripheral circuit region (not shown).

Referring to FIGS. 3 and 4C, the photoresist patterns (406 of FIG. 4B) are removed. A third polysilicon layer 407 for control gates and a silicide layer 408 are formed over the resulting structure including the second polysilicon layer 404. The first polysilicon layer 403 and the third polysilicon layer 407 are electrically and physically connected to each other in the region in which the dielectric layer 404 is removed. Here, the third polysilicon layer 407 is formed at a thickness of 500 to 1000 Å, and the silicide layer 408 is formed by using tungsten.

Thereafter, a hard mask 409 for defining word line and select line patterns is formed on the silicide layer 408. In the conventional arts, an interval between the select line patterns is defined larger than an interval between the word line patterns in order to form contacts for electrically connecting the first polysilicon layer 403 for the floating gates to the third polysilicon layer 407 for the control gates. For example, in the case of 90 nm flash memory device, the interval between the word line patterns is defined as 95 nm, and the interval between the select line patterns is defined as 220 nm to form the contacts. However, in accordance with the present invention, the hard mask 409 is patterned to equalize the interval between the select line patterns to the interval between the word line patterns.

Because the interval between the select line patterns is equalized to the interval between the word line patterns, regularity of the patterns is achieved. As a result, in the patterning process of the hard mask 409, photoresist patterns (not shown) formed on the hard mask 409 are not collapsed, and select line patterns are not thinly defined.

As shown in FIGS. 3 and 4D, an etching process is performed by using the hard mask 409 as an etch mask. Here, the etching process is performed by setting the dielectric layer 404 as an etch barrier layer in the region in which the dielectric layer is left, and setting the tunnel oxide layer 402 as the etch barrier layer in the region in which the dielectric layer 404 is removed. In the peripheral circuit region (not shown), the silicide layer and the polysilicon layer are etched by using a gate oxide layer (not shown) as an etch barrier layer.

In the case that the lower layers are patterned in the above conditions, the silicide layer 408, the third polysilicon layer 407 and the first polysilicon layer 403 are sequentially etched between the presumed source select line or drain select line formation regions, thereby exposing the tunnel oxide layer 402. The silicide layer 408 and the third polysilicon layer 407 are etched between the presumed word line formation regions, thereby exposing the dielectric layer 404. On the other hand, the third polysilicon layer 407 is formed in the presumed source select line or drain select line formation regions in a state where the dielectric layer 404 is partially removed, and thus the first polysilicon layer 403 and the third polysilicon layer 407 are patterned in an electrical and physical connection state.

As illustrated in FIGS. 3 and 4E, a photoresist pattern 410 is formed to cover the tunnel oxide layer 402 exposed between the presumed source select line or drain select line formation regions. When the tunnel oxide layer 402 is removed in a succeeding etching process, the photoresist pattern 410 prevents etching damages from occurring on the semiconductor substrate 401.

As depicted in FIGS. 3 and 4F, the dielectric layer 404 exposed in the cell region, and the first polysilicon layer 403 formed below the dielectric layer 404 are sequentially etched according to a self aligned etching process, to form control gates 411 including the silicide layer 408 and the third polysilicon layer 407, and floating gates 403 including the first polysilicon layer 403. The photoresist pattern (410 of FIG. 4E) is removed.

Accordingly, the select lines DSL and SSL in which the control gates 411 and the floating gates 403 are coupled to each other are formed at regular intervals from a plurality of word lines WLa1 to WLan and WLb1 to WLbn.

As discussed earlier, in accordance with the present invention, the NAND type flash memory device and the method for manufacturing the same can prevent the patterns from being collapsed or thinly defined due to irregularity, by forming the word lines or select lines in regular patterns, by electrically connecting the floating gates and control gates of the select lines without using contacts, and also can improve integration by omitting gate pads.

Although the present invention has been described in connection with the embodiment of the present invention illustrated in the accompanying drawings, it is not limited thereto. It will be apparent to those skilled in the art that various substitutions, modifications and changes may be made thereto without departing from the scope and spirit of the invention.

1. A NAND type flash memory device, comprising:
tunnel oxide patterns formed on a semiconductor substrate;
first polysilicon patterns formed on the tunnel oxide patterns, wherein the first polysilicon patterns include a first group for floating gates and a second group for parts of select lines;
dielectric patterns formed on the floating gates; and
conductive patterns including first conductive patterns formed on the dielectric patterns and second conductive patterns formed on the second group of the first polysilicon patterns, wherein the first conductive patterns form control gates and second conductive patterns form select lines with the second group of the first polysilicon patterns.

2. The method of claim 1, further comprising another dielectric patterns covering portions of the second group of the first polysilicon patterns.

3. The method of claim 1, wherein the first conductive patterns include:
second polysilicon patterns formed on the dielectric patterns;
third polysilicon patterns formed on the second polysilicon patterns; and
first silicide patterns formed on the third polysilicon patterns.

4. The method of claim 3, wherein the second conductive patterns include:
fourth polysilicon patterns formed on the second group of the first polysilicon patterns; and
second silicide patterns formed on the fourth polysilicon patterns.

5. A method for manufacturing a NAND type flash memory device, comprising the steps of:
providing a semiconductor substrate on which an element isolation film is formed in an element isolation region and a stacked structure of a tunnel oxide film and a first polysilicon layer is formed on an active region between the element isolation films at regular intervals;
forming a dielectric film over the resulting structure including the first polysilicon layer;
removing the dielectric film in presumed source select line or drain select line formation regions;
sequentially forming a second polysilicon layer, a silicide layer and hard mask patterns over the resulting structure including the dielectric film; and
forming a plurality of word lines and a plurality of select lines, by sequentially performing an etching process and a self aligned etching process using the hard mask patterns as an etch barrier film.

6. The method of claim 5, wherein the dielectric film is protectively removed after a polysilicon layer for protection is formed on the dielectric film.

7. The method of claim 5, wherein the dielectric film is partially removed so that the dielectric film can be left in part of the presumed source select line or drain select line formation regions.

8. The method of claim 5, wherein, in the etching process, the dielectric film is used as the etch barrier film in the region in which the dielectric film is left, and the tunnel oxide film is used as the etch barrier film in the region in which the dielectric film is removed.

9. The method of claim 5, wherein a photoresist pattern is formed in the region in which the tunnel oxide film is exposed according to the etching process prior to the self aligned etching process.
